(19) United States
(12) Patent Application Publication
(10) Pub. No.: US 2023/0317620 A1
(43) Pub. Date: Oct. 5, 2023

(54) INTERPOSERS FOR SEMICONDUCTOR DEVICES

(71) Applicant: Intel Corporation, Santa Clara, CA (US)

(72) Inventors: Carlton Hanna, San Jose, CA (US); Georg Seidemann, Landshut (DE); Eduardo De Mesa, Munich (DE); Abdallah Bacha, Munich (DE); Lizabeth Keser, San Diego, CA (US)

(21) Appl. No.: 17/708,746

(22) Filed: Mar. 30, 2022

(51) Int. Cl. H01L 23/538; H01L 23/15; H01L 25/065; H01L 21/48

(52) U.S. Cl. CPC H01L 23/5383; H01L 23/15; H01L 24/16; H01L 21/4857; H01L 25/0655

(57) ABSTRACT

Various embodiments disclosed relate to a semiconductor assembly having a ceramic or glass interposer for connecting dies within a semiconductor package. The present disclosure includes a ceramic or glass interposer having a carrier layer of substantially glass or ceramic material and a connecting layer having at least one dielectric layer and electrical routing therein.

### TECHNICAL FIELD

Embodiments described herein generally relate to semiconductor devices and packaging.

### BACKGROUND

Multi-die packages can use interposers for electrical connections between dies and mechanical stability of the packages. Larger packages can use interposers with fine line spacing for more efficient connections. It is desired to have interposers that address these concerns, and other technical challenges.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 depicts a schematic diagram of a semiconductor assembly in an example.

FIGS. 2A to 2C depict schematic diagrams of an interposer with a ceramic layer in an example.

FIGS. 3A to 3C depict schematic diagrams of an interposer with a glass layer in an example.

FIGS. 4A to 4B depict schematic of a double layer interposer in an example.

FIG. 5 depicts a method of making an interposer in an example.

FIG. 6 depicts a schematic of a computer system in an example.

FIG. 7 depicts a process flow for production of a multi-die package including a glass or ceramic layer and a BEOL layer in an example.

FIG. 8 depicts a process flow for production of a multi-die package including a glass or ceramic layer and a BEOL layer in an example.

### DETAILED DESCRIPTION

Discussed herein is an interposed architecture using a ceramic or glass material as a base layer for a back end of the line (BEOL) process. Multi-die packages, both 2D and 3D, can require interposers for electrical connections between dies and mechanical stability of the package. The use of a ceramic or glass-based interposer with a BEOL layer can help keep electrical performance, while reducing the cost of interposers relative to conventional silicon-based interposers.

Such ceramic or glass interposers can allow for an increased performance compared to conventional organic or silicon interposers. Ceramic or glass interposers can realize fine pitches, such as below 1.5 micrometers. Ceramic or glass interposers can, for example, be used in large packages where fine line spacing is desired. Such interposers can allow for high density interconnects at a lower cost.

Ceramic or glass interposers can be set-up using a BEOL process, and adhesion adaption can be done between a ceramic interposer and a BEOL layer by an oxide layer (such as a dieletrics). Such ceramic or glass interposers can provide good mechanical reliability, electrical dissipation, and good thermal conductivity (such as with a ceramic), while reducing CTE mismatch.

In an example, an assembly can include a first die, a second die, and an interposer electrically connecting the first die and the second die, wherein the interposer comprises a base layer comprising glass or ceramic, and a connecting layer comprising a back end of the line layer.

In an example, an interposer configured for electrical connection of two or more dies within a semiconductor assembly can include a base layer comprising a glass or ceramic material and a back end of the line stack thereon, the back end of the line stack comprising at least one dielectric layer and one or more conductive traces therein, wherein the base layer is configured to host the back end of the line stack. The dieletric layer can include, for example, polyimide, or other oxides.

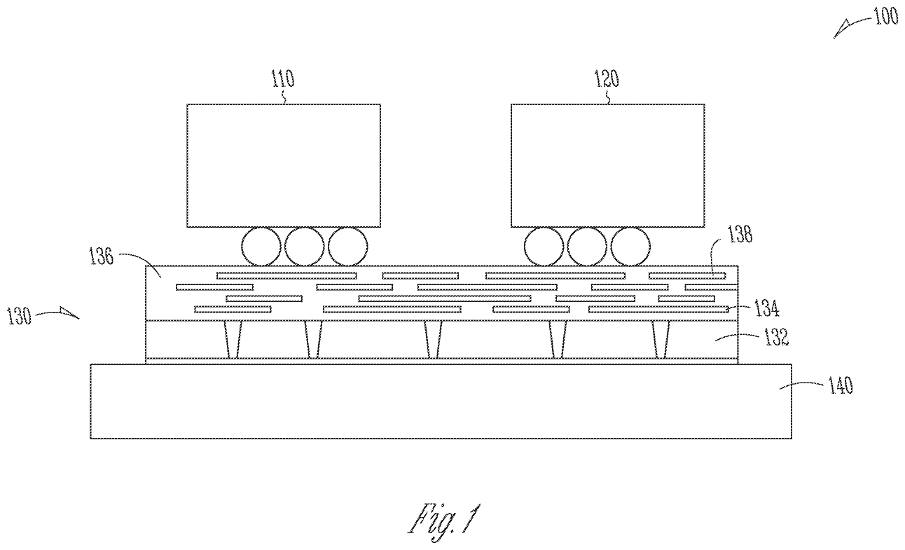

FIG. 1 depicts a schematic diagram of a semiconductor assembly 100 in an example. The assembly 100 can include a first die 110, a second die 120, an interposer 130, a package substrate 140, and ball grid array 150.

The first die 110 and the second die 120 can be semiconductor dies mounted on package substrate 140. The first die 110 and the second die 120 can be, for example, any of a central processing unit (CPU), a platform controller hub/chipset die (PCH), a graphic processing unit (GPU), a memory die, a field programmable gate array (FGPA) or other semiconductor die. The first die 110 and the second die 120 can be electrically coupled to each other through the interposer 130.

The interposer 130 can include both a base layer 132 and a connection layer 134. The base layer 132 can include via 133. The connection layer 134 can include dielectric layers 136 and conductive traces 138. The connection layer 134 can, for example, be made by a back end of the line (BEOL) process. The interposer can provide for mechanical stability and robustness of the assembly 100, while allowing electrical connection of the dies 110, 120.

The base layer 132 can be made of a ceramic material or a glass material, such as a layer or matrix of glass or ceramic. For example, the base layer 132 can be a silicon oxide glass. In some cases, the base layer 132 can be a glass formed by plasma process. The base layer 132 can be a ceramic, such as alumina, aluminum nitride, or silicon carbide.

The connection layer 134 can include a dielectric material, such as in a plurality of layers built up by BEOL. The connection layer 134 can further include electrical routing, such as metallic traces. In some cases, the base layer 132 can include one or more through glass via or through ceramic via electrically connecting to the connection layer 134.

The substrate 140 can be, for example, a semiconductor package substrate hosting one or more semiconductor dies such as dies 110, 120. Package substrate 140 can be connected to semiconductor dies 110, 120, through the interposer 130. Traces, and other pads or via, can allow for electrical connection through package substrate 140 to other components mounted on a circuit board. In some cases, the package substrate 140 can be mounted on a circuit board, such as a printed circuit board (PCB) that mechanically and electrically supports components in the assembly 100, or another type of motherboard.

The ball grid arrays 150 can be used to connect the dies 110, 120. The ball grid arrays 150 can be solder balls, such as made of conductive solder in an appropriate pattern to create electrical connections. Solder balls 150 can be connected to traces in the interposer 130, made of a conductive material. The BGA can be underfilled with an appropriate adhesive, such as, for example, epoxy or other adhesive as known in the art.

In some embodiments, the interconnects can be, for example, solder balls, such as ball grid arrays (BGA) made of conductive solder in an appropriate pattern to create electrical connections. Solder balls can be connected via solder ball pads, made of a conductive and/or metallic material, such as copper. In order to make solder balls with larger diameter (i.e., wider), the solder balls must also be taller. This is due to surface tension of the solder ball material. For this reason, a recess can be a convenient solution to provide a “taller” space in which larger solder balls can reside. Wider solder balls additionally have a lower resistance, and thus can address the hot spot problems discussed above. The BGA can be underfilled with an appropriate adhesive, such as, for example, epoxy or other adhesive as known in the art.

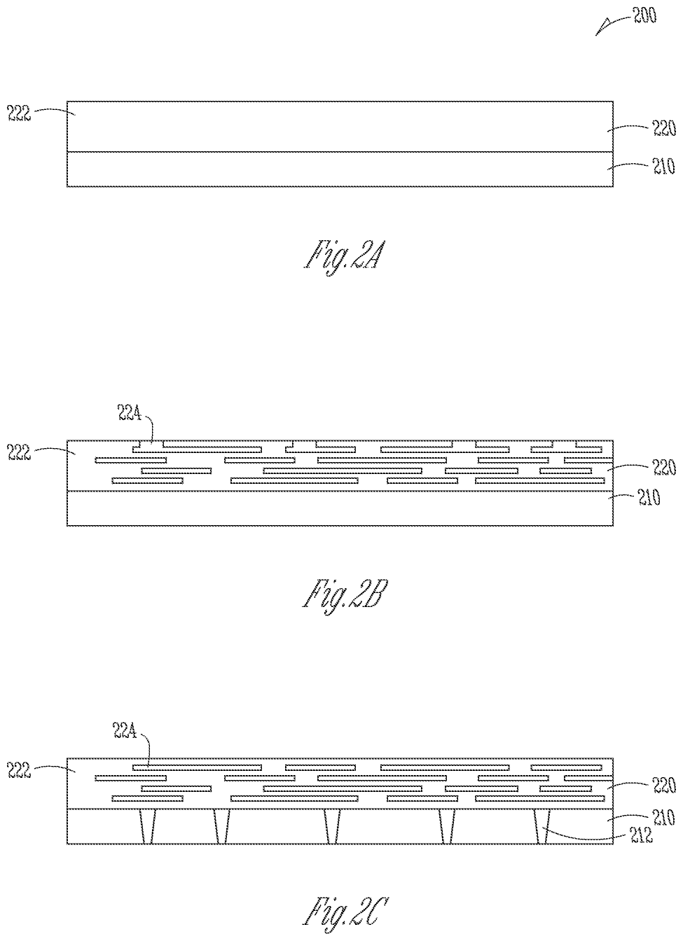

FIGS. 2A to 2C depict schematic diagrams of an interposer 200 with a ceramic layer in an example. The interposer 200 can include a ceramic base layer 210 and a connection layer 220. The ceramic base layer 210 can include via 212. The connection layer 220 can include a plurality of dielectric layers 222 and metallic traces 224. The interposer 200 can be similar to the interposer 130 discussed above.

Shown in FIG. 2A, the base layer 210 can be made of a ceramic material, connected to the connection layer 220. The connection layer 220 can include a dielectric material 222 that can form multiple dielectric layers. The base layer 210 can be attached to the connection layer 220, such as by a lamination process, with a nitride layer, or other methods. In some cases, a sintering method can be used to join the layers.

In FIG. 2B, the connection layer 220 can additionally include one or more conductive traces or metallic lines 224. The connection layer 220 can allow for fine line spacing. For example, the connection layer 220 can have fine pitches, such as below 1.5 micrometers.

The connection layer 220 can be built up with a BEOL technique, such as with copper or aluminum metal deposition. BEOL processes can include, for example, silicidation of source and drain regions and the polysilicon region, adding a first dielectric (e.g., a pre-metal dielectric (PMD) such as to isolate metal from silicon and polysilicon), making holes in the PMD, and making contacts in the holes. Next, a first metal layer can be made, followed by a second dielectric layer (e.g., an inter-metal dielectric (IMD)). Vias can then be made through dielectric material to connect lower metal with higher metal. This can be done, for example, by a deposition process. These steps can be repeated to build up subsequent layers of dielectric and conductive traces.

In FIG. 2C, via 212 are shown in the base layer 210. The via 212 can be through ceramic via (TCV) such as to allow connection from the connection layer 210 to components on an opposing side of the base layer 220.

The interposer 200 with the ceramic base layer 210 can help reduce coefficient of thermal expansion (CTE) mismatch within the assembly. In some cases, depending on the ceramic material used, heat dissipation or conduction can be tailored within the interposer 200.

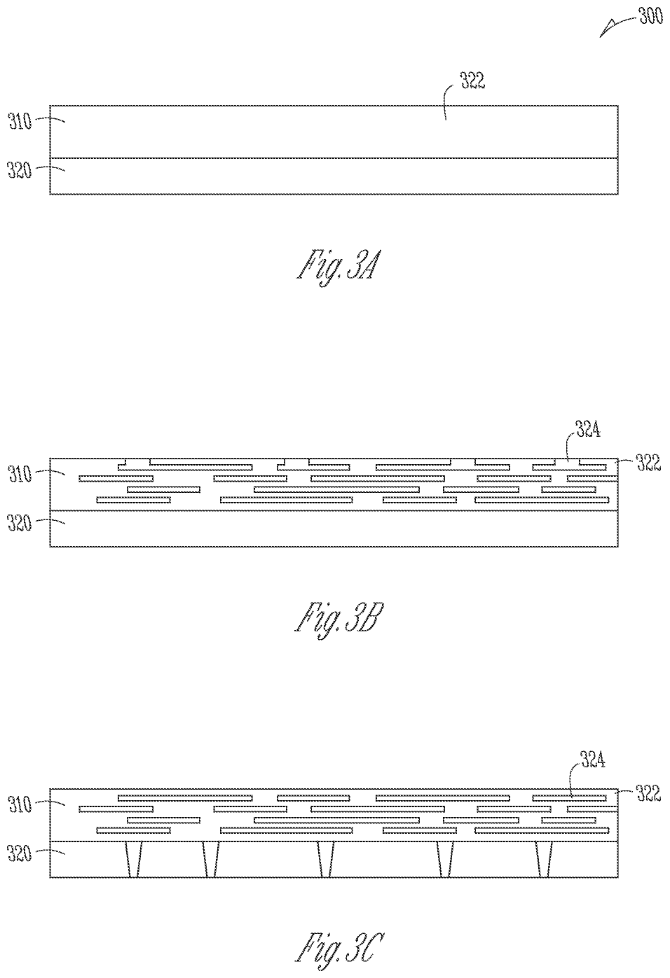

FIGS. 3A to 3C depict schematic diagrams of an interposer with a glass layer in an example. The interposer 300 can include a glass base layer 310 and a connection layer 320. The glass base layer 310 can include via 312. The connection layer 320 can include a plurality of dielectric layers 322 and metallic traces 324.

The components of interposer 300 are similar to those discussed with reference to interposer 200 above, except that the base layer 310 can be made of glass. The glass material can, for example, be a silicon oxide glass, or a glass formed by plasma processes. In some cases, the use of a glass material can help dissipate heat within the assembly.

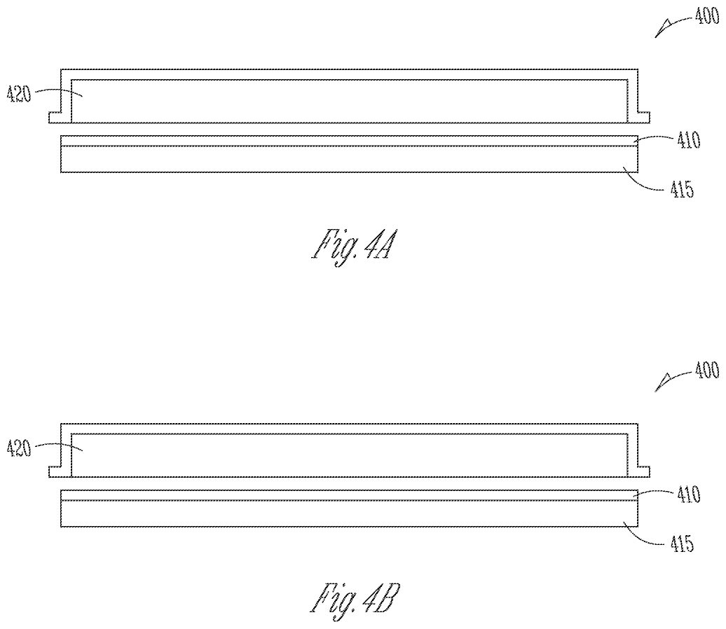

FIGS. 4A to 4B depict schematic of a double layer interposer 400 in an example. The interposer 400 can include a first glass base layer 410, a second glass base layer 415, and a connection layer 420. The first glass base layer 410 and the second glass base layer 415 can be connected through an adhesion layer 418. The connection layer 420 can include a plurality of dielectric layers 422 and metallic traces 424.

The first glass base layer 410 and the second glass base layer can be attached to each other into a single base. For example, the first glass base layer 410 and the second glass base layer can be joined by appropriate bonds, by adhesive, or by other methods. The first glass base layer 410 and the second glass base layer can be of similar materials and thicknesses. In some cases, the first glass base layer 410 and the second glass base layer can be of differing materials. In some cases, the first glass base layer 410 and the second glass base layer can be of differing thicknesses.

The first glass base layer 410 and the second glass base layer can each have differing warpages. For example, shown in FIG. 4A, the first glass base layer 410 can have a positive warpage, while the second glass base layer 415 can have a negative warpage. This can help reduce overall warpage in the interposer. Shown in FIG. 4B, the first glass base layer 410 can have a first thickness, while the second glass base layer 415 can have a second thickness.

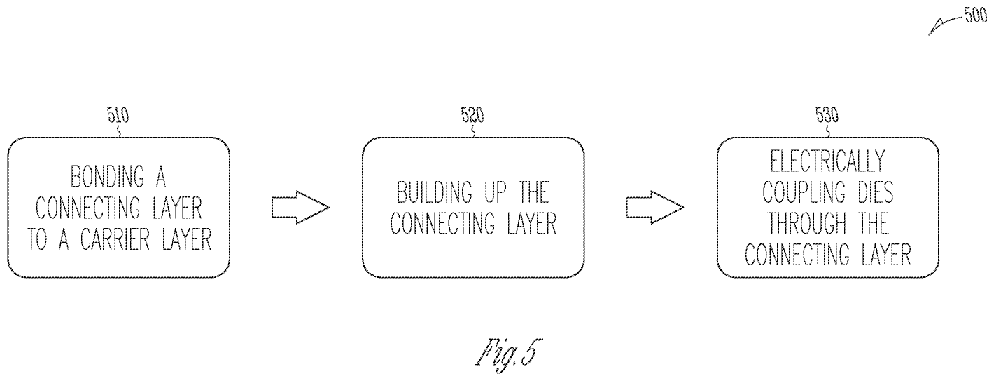

FIG. 5 depicts a method 500 of making an interposer in an example. The method 500 can include blocks 510 to 530.

First, at block 510, the connecting layer can be bonded to the base layer. Depending on the type of base layer material, different bonding techniques can be used. For example, with a ceramic base layer, a sintering process can be used. With a glass base layer, other adhesives can be used. In some cases, aluminum and aluminum oxide can be used. Lamination processes can also be used. In some cases, multiple layers of base material can be bonded together to form the base layer.

Next, at block 520, the connecting layer can be built up, such as by a BEOL process as described above. This can allow for building of dielectric layers, and metallic traces therein. The connecting layer can be built with a desired number of dielectric layers and traces.

At block 530, the interposer can be attached within the assembly, such as on a package substrate or circuit board. The interposer can be electrically connected to semiconductor dies, such as through solder ball, via, or other connecting elements.

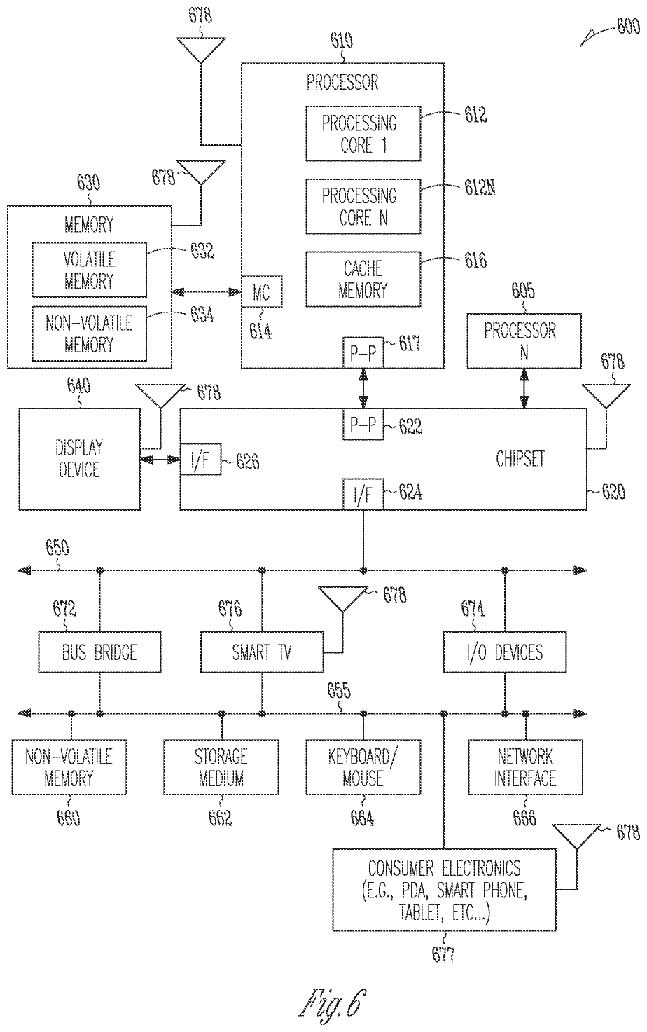

FIG. 6 depicts a schematic of a computer system in an example. FIG. 6 illustrates a system level diagram, depicting an example of an electronic device (e.g., system) that may include an interposer and/or methods described above. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 includes a system on a chip (SOC) system.

In one embodiment, processor 610 has one or more processor cores 612 and 612N, where 612N represents the Nth processor core inside processor 610 where N is a positive integer. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Home Plug AV (HPAV), Ultra Wide Band (UWB), Bluetooth, WiMAXs, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments of the example system, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a PDA, smart phone, tablet etc.), etc. In one embodiment, chipset 620 couples with these devices through an interface 624. Chipset 620 may also be coupled to a wireless antenna 678 to communicate with any device configured to transmit and/or receive wireless signals. In one example, any combination of components in a chipset may be separated by a continuous flexible shield as described in the present disclosure.

Chipset 620 connects to display device 640 via interface 626. Display 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single SOC. In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMAX, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

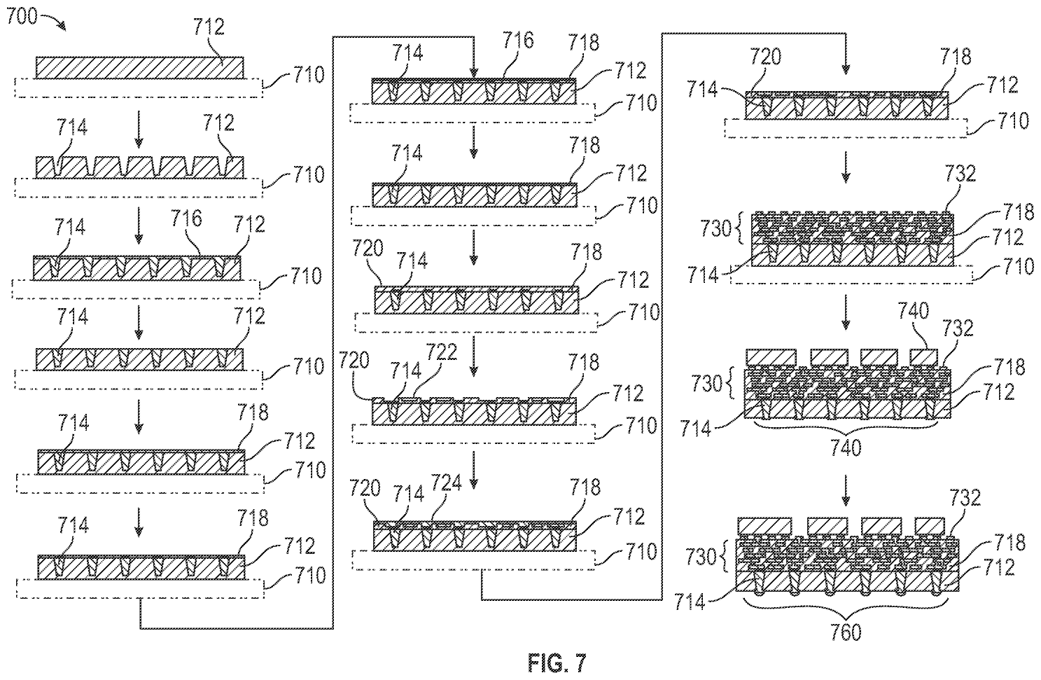

FIG. 7 depicts a process flow 700 for production of a multi-die package including a glass or ceramic layer and a BEOL layer in an example. The production of the multi-die package involves a production carrier 710, a glass or ceramic layer 712, vias 714, copper deposition 716, oxide layer 718, second oxide layer 720, openings 722, second copper deposition 724, copper metaliziation 730, pads 732, dies 740, and attachment mechanisms 740, 760.

First, the desired glass or ceramic layer 712, such as desired in detail above, can be attached to a production carrier 710. Next, through glass via (TGV) or through ceramic via (TCV) can be formed in the glass or ceramic layer 712. These TGV or TCV 714 can be filled, such as with copper deposition 716. Once the TGV or TCV 714 are filled, the top layer of the copper deposition 716 can be removed, such as by etching. The first oxide layer 718 can then be deposited. Openings, such as lines, can be created in the first oxide layer 718. This can be followed by another copper deposition 716, which can similarly be selectively removed to form appropriate lines within the oxide layer 718. A second oxide layer 720 can then be built up. Openings 722 or lines can be formed in the second oxide layer 720. Another copper deposition 724 can be built up to fill the openings 722 as desired, which can be selectively removed. The entire copper metalization (BEOL) 730 can be built up in such a fashion, such as with alternating oxide layers and copper layers.

Pads 732 can be formed on the topmost surface of the copper metalization 730. In other examples, a variety of materials may be used for the BEOL layer 730. The semiconductor dies 740 can be attached to the pads 732, such as through solder or a ball-grid array. The production carrier 710 can be detached from the glass or ceramic layer 712, and bonding methods can be used on the opposing side of the vias 714. For example, copper bonding 750 can be used. In some cases, glass or ceramic grinding and soldering 760 can be used.

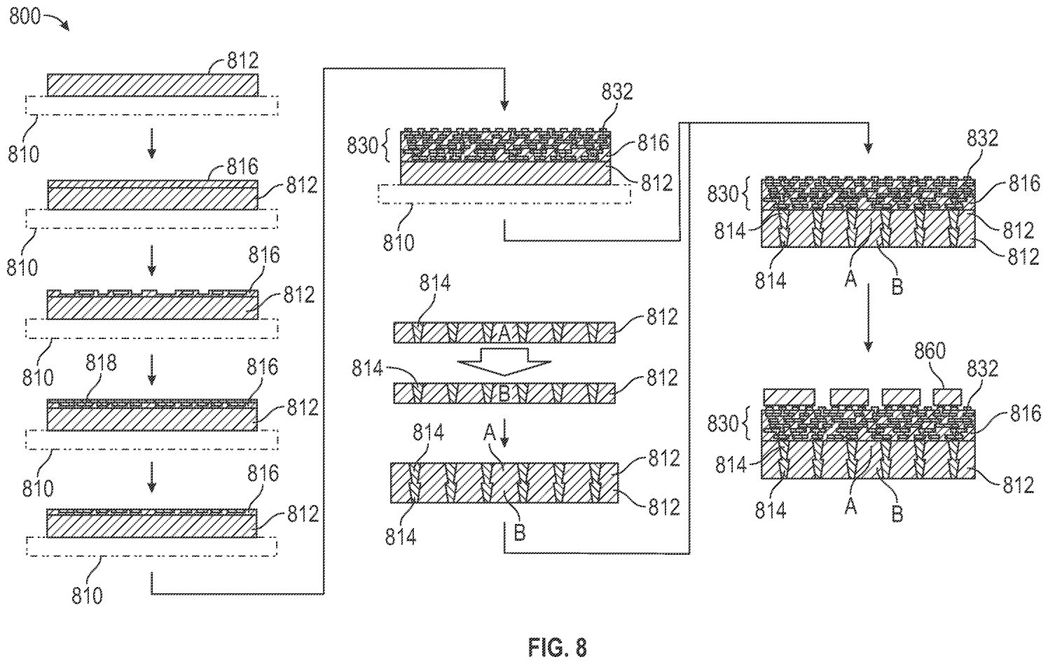

FIG. 8 depicts a process flow 800 for production of a multi-die package including a glass or ceramic layer and a BEOL layer in an example. The process flow 800 can involve a production carrier 810, a glass or ceramic layer 812, an oxide layer 816, a copper deposition 818, a copper metalization (BEOL) 830, and pads 832. An interposer can simultaneously be prepared with a glass or ceramic layer 812 and vias 814.

In example process flow 800, the glass or ceramic layer 812 can be situated on a production carrier 810. The oxide layer 816 can be deposited thereon, followed by production of lines on the oxide layer 816. The copper layer 818 can be deposited on the oxide layer 816 to fill the lines, and can subsequently be selectively removed. Similar to process 700 above, the copper metalization (BEOL) 830 can be built up in this manner.

Meanwhile, an interposer with a ceramic or glass layer 812 can be created with via 814. In some cases, two such interposers can be made and attached, such as by wafer to wafer bonding or hybrid bonding. This can be similar to the configurations discussed with reference to FIGS. 4A to 4B above. These interposers can then be stacked with the BEOL layer 830 on initial glass or ceramic layer 812, and dies 860 can be attached.

In some cases, the assembly of FIG. 8 can be a bridge component without TSV. In some cases, the assembly of FIG. 8 can be an assembly with a base layer of multiple layers of glass or ceramic. In some cases, this can be a multi glass base layer, multi ceramic base layer or a multi combined glass-ceramic base layer

### VARIOUS NOTES & EXAMPLES

Example 1 is an assembly comprising: a first die; a second die; and an interposer electrically connecting the first die and the second die, the interposer comprising: a carrier layer of substantially glass or ceramic material; and a connecting layer having at least one dielectric layer and electrical routing therein.

In Example 2, the subject matter of Example 1 optionally includes wherein the connecting layer comprises a back end of the line stack.

In Example 3, the subject matter of any one or more of Examples 1-2 optionally include wherein the carrier layer comprise a ceramic selected from the group consisting of alumina, aluminum nitride, and use silicon carbide.

In Example 4, the subject matter of any one or more of Examples 1-3 optionally include wherein the carrier layer comprises a glass made by a plasma process.

In Example 5, the subject matter of any one or more of Examples 1-4 optionally include wherein the carrier layer further comprises one or more through glass via or through ceramic via.

In Example 6, the subject matter of any one or more of Examples 1-5 optionally include wherein the connecting layer comprises a plurality of dielectric layers and electrically conductive components.

In Example 7, the subject matter of any one or more of Examples 1-6 optionally include wherein the carrier layer comprising two glass layers.

In Example 8, the subject matter of Example 7 optionally includes wherein the two glass layers are attached to each other with an adhesive.

In Example 9, the subject matter of any one or more of Examples 7-8 optionally include wherein the two glass layers are attached to each other with glass-to-glass bonds.

In Example 10, the subject matter of any one or more of Examples 7-9 optionally include wherein the two glass layers comprise a first glass layer with a first thickness and a second glass layer with a second thickness.

In Example 11, the subject matter of Example 10 optionally includes wherein the first thickness is different from the second thickness.

In Example 12, the subject matter of any one or more of Examples 7-11 optionally include an oxide layer bonding the two glass layers together.

Example 13 is an interposer configured for electrical connection of two or more dies within a semiconductor assembly, the interposer comprising: a carrier layer comprising a glass or ceramic material; and a connecting layer thereon, the connecting layer comprising at least one dielectric layer and one or more conductive traces therein, wherein the carrier layer is configured to host the connecting layer.

In Example 14, the subject matter of Example 13 optionally includes a substrate layer attached to the carrier layer opposite the connecting layer.

In Example 15, the subject matter of any one or more of Examples 13-14 optionally include wherein the carrier layer comprises two or more layers of the glass or ceramic material.

In Example 16, the subject matter of Example 15 optionally includes one or more bonds between the two or more layers.

In Example 17, the subject matter of any one or more of Examples 13-16 optionally include one or more through via in the carrier layer.

Example 18 is a method of making an interposer, comprising: building a connecting layer on a carrier layer, wherein building a connecting layer comprises a back end of the line method to produce one or more dielectric layers with conductive traces therein, wherein the carrier layer comprises a ceramic material or a glass material.

In Example 19, the subject matter of Example 18 optionally includes bonding two portions of the carrier together before building the connecting layer.

In Example 20, the subject matter of any one or more of Examples 18-19 optionally include attaching a substrate to the carrier opposite the connecting layer.

Each of these non-limiting examples can stand on its own, or can be combined in various permutations or combinations with one or more of the other examples.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code may form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. An assembly comprising:
a first die;
a second die; and
an interposer electrically connecting the first die and the second die, the interposer comprising:
a base layer of substantially glass or ceramic material; and
a connecting layer having at least one dielectric layer and electrical routing therein.

2. The assembly of claim 1, wherein the connecting layer comprises a back end of the line stack.

3. The assembly of claim 1, wherein the carrier layer comprise a ceramic selected from the group consisting of alumina, aluminum nitride, and silicon carbide.

4. The assembly of claim 1, wherein the carrier layer comprises a glass made by a plasma melting process.

5. The assembly of claim 1, wherein the carrier layer further comprises one or more through glass via or through ceramic via.

6. The assembly of claim 1, wherein the connecting layer comprises a plurality of dielectric layers and electrically conductive components.

7. The assembly of claim 1, wherein the connecting layer comprises a back end of the line layers.

8. The assembly of claim 1, wherein the carrier layer comprising two glass layers.

9. The assembly of claim 8, wherein the two glass layers are attached to each other with an adhesive.

10. The assembly of claim 8, wherein the two glass layers are attached to each other with glass-to-glass bonds.

11. The assembly of claim 8, wherein the two glass layers comprise a first glass layer with a first thickness and a second glass layer with a second thickness.

12. The assembly of claim 8, further comprising an oxide layer bonding the two glass layers together.

13. An interposer configured for electrical connection of two or more dies within a semiconductor assembly, the interposer comprising:
a carrier layer comprising a glass or ceramic material; and
a connecting layer thereon, the connecting layer comprising at least one dielectric layer and one or more conductive traces therein, wherein the carrier layer is configured to host the connecting layer.

14. The interposer of claim 13, further comprising a substrate layer attached to the carrier layer opposite the connecting layer.

15. The interposer of claim 13, wherein the carrier layer comprises two or more layers of the glass material, ceramic material, or combinations thereof.

16. The interposer of claim 15, further comprising one or more bonds between the two or more layers.

17. The interposer of claim 13, further comprising one or more through via in the carrier layer.

18. A method of making an interposer, comprising:
building a connecting layer on a carrier layer, wherein building a connecting layer comprises a back end of the line method to produce one or more dielectric layers with conductive traces therein, wherein the carrier layer comprises a ceramic material or a glass material.

19. The method of claim 18, further comprising bonding two portions of the carrier together before building the connecting layer.

20. The method of claim 18, further comprising attaching a substrate to the carrier opposite the connecting layer.
